(19) United States
(12) Patent Application Publication
(10) Pub. No.: US 2023/0154728 A1
(43) Pub. Date: May 18, 2023

(54) Methods and Systems for Controlling Radiofrequency Pulse-Initiation Power Spike for Plasma Sheath Stabilization

(71) Applicant: Lam Research Corporation, Fremont, CA (US)

(72) Inventors: Ying Wu, Livermore, CA (US); Alexander Miller Paterson, San Jose, CA (US); Neema Rastgar, San Jose, CA (US); John Drewery, San Jose, CA (US)

(21) Appl. No.: 17/916,643

(22) PCT Filed: Apr. 1, 2021
(86) PCT No.: PCT/US2021/025424

§ 371 Date: Oct. 3, 2022

Related U.S. Application Data
(60) Provisional application No. 63/006,048, filed on Apr. 6, 2020.

(51) Int. Cl. H01J 37/32; H01L 21/311; H01L 21/3213

(52) U.S. Cl. CPC H01J 37/32146; H01J 37/32568; H01J 37/32119; H01J 37/32165; H01L 21/31122; H01L 21/32136; H01J 2237/334

(57) ABSTRACT

Multiple, sequential pulses of radiofrequency power are supplied to an electrode of a plasma processing chamber to control a plasma within the plasma processing chamber. Each of the pulses of radiofrequency power includes a first duration over which a first radiofrequency power profile exists, immediately followed by a second duration over which a second radiofrequency power profile exists. The first radiofrequency power profile has greater radiofrequency power than the second radiofrequency power profile. The first duration is less than the second duration. And, the sequential pulses of radiofrequency power are separated from each other by a third duration. A radiofrequency signal generation system is provided to generate and control the multiple, sequential pulses of radiofrequency power.

### BACKGROUND

### 1. Field of the Disclosure

The present disclosure relates to semiconductor device fabrication.

### 2. Description of the Related Art

In the fabrication of semiconductor devices such as integrated circuits, memory cells, and the like, a series of manufacturing operations are performed to define features on a semiconductor wafer (“wafers” hereafter). The wafer includes integrated circuit devices in the form of multi-level structures defined on a silicon substrate. At a substrate level, transistor devices with diffusion regions are formed. In subsequent levels, interconnect metallization lines are patterned and electrically connected to the transistor devices to define a desired integrated circuit device. Also, patterned conductive layers are insulated from other conductive layers by dielectric materials.

Many modern semiconductor chip fabrication processes include generation of a plasma from which ions and/or radical constituents are derived for use in either directly or indirectly affecting a change on a surface of a substrate exposed to the plasma. For example, various plasma-based processes can be used to etch material from a substrate surface, deposit material onto a substrate surface, or modify a material already present on a substrate surface. The plasma is often generated by applying radiofrequency (RF) power to a process gas in a controlled environment, such that the process gas becomes energized and transforms into the desired plasma. The characteristics of the plasma are affected by many process parameters including, but not limited to, material composition of the process gas, flow rate of the process gas, geometric features of the plasma generation region and surrounding structures, temperatures of the process gas and surrounding materials, frequency of the RF power applied, magnitude of the RF power applied, and temporal manner in which the RF power is applied, among others. Therefore, it is of interest to understand, monitor, and/or control some of the process parameters that may affect the characteristics of the generated plasma, particularly with regard to delivery of the RF power to the plasma generation region. It is within this context that the present disclosure arises.

### SUMMARY

In an example embodiment, a method is disclosed for controlling a plasma within a plasma processing chamber. The method includes supplying multiple, sequential pulses of RF power to an electrode of the plasma processing chamber. Each of the pulses of RF power includes a first duration over which a first RF power profile exists, immediately followed by a second duration over which a second RF power profile exists. The first RF power profile has greater RF power than the second RF power profile. The first duration is less than the second duration. And, the sequential pulses of RF power are separated from each other by a third duration.

In an example embodiment, a controller is programmed to control a plasma within a plasma processing chamber. The controller includes program instructions stored in a computer memory that when executed direct supplying of multiple, sequential pulses of RF power to an electrode of the plasma processing chamber. Each of the pulses of RF power includes a first duration over which a first RF power profile exists, immediately followed by a second duration over which a second RF power profile exists. The first RF power profile has greater RF power than the second RF power profile. The first duration is less than the second duration. And, the sequential pulses of RF power are separated from each other by a third duration.

In an example embodiment, an RF signal generation system is configured to control a plasma within a plasma processing chamber. The RF signal generation system includes an RF signal generator configured to generate RF signals at or near a set frequency. The RF signal generation system also includes a first direct current voltage supply connected to a voltage input of the RF signal generator. The RF signal generation system also includes a second direct current voltage supply switchably connected to the voltage input of the RF signal generator. The RF signal generation system also includes a controller configured and connected to control each of the RF signal generator, the first direct current voltage supply, and the second direct current voltage supply. The voltage supplied to the voltage input of the RF signal generator by the first and second direct current voltage supplies controls an amplitude of the RF signals generated by the RF signal generator.

In an example embodiment, a method is disclosed for controlling a plasma within a plasma processing chamber. The method includes supplying multiple, sequential pulses of primary RF power to a primary electrode of the plasma processing chamber. Each of the pulses of primary RF power includes a first duration over which a first primary RF power profile exists, immediately followed by a second duration over which a second primary RF power profile exists. The first primary RF power profile has greater RF power than the second primary RF power profile. The first duration is less than the second duration. And, the sequential pulses of primary RF power are separated from each other by a third duration. The method also includes supplying multiple, sequential pulses of bias RF power to a bias electrode of the plasma processing chamber. Each of the pulses of bias RF power includes a fourth duration over which a first bias RF power profile exists, immediately followed by a fifth duration over which a second bias RF power profile exists. The first bias RF power profile has greater RF power than the second bias RF power profile. The fourth duration is less than the fifth duration. And, the sequential pulses of bias RF power are separated from each other by a sixth duration.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1A shows a vertical cross-section view of a plasma processing system for use in manufacturing semiconductor wafers, in accordance with some embodiments.

FIG. 1B shows a top view of the plasma processing system of FIG. 1A, in accordance with some embodiments.

FIG. 2 shows an example arrangement of the control system, in accordance with some embodiments.

FIG. 3A shows a square-shaped RF power pulse profile that may be supplied by the bias RF signal generator to the bias electrode to generate the bias voltage, in accordance with some embodiments.

FIG. 3B shows the square-shaped RF power pulse profile of FIG. 3A, with an initial spike of RF power associated with the initial masking time of the bias RF signal generator, in accordance with some embodiments.

FIG. 4 shows an RF power pulse profile that includes RF pulse-initiation power spiking, in accordance with some embodiments.

FIG. 5 shows an RF power pulse profile that represents dual-level RF power pulsing in which the RF power is pulsed between a first set non-zero power level P1 and a set power level P2, with the first RF power profile p1 having the set power level P3, in accordance with some embodiments.

FIG. 6 shows an RF power pulse profile that represents single-level RF power pulsing in which the RF power is pulsed between zero and a set power level P1, with a first RF power profile p1 that exceeds the set power level P1 and is non-constant, in accordance with some embodiments.

FIG. 7 shows an RF power pulse profile that represents single-level RF power pulsing in which the RF power is pulsed between zero and a set power level P1, with a first RF power profile p1 that exceeds the set power level P1 and is non-constant, in accordance with some embodiments.

FIG. 8A shows the RF power pulse profile of FIG. 4 with frequency variation applied over the pulse duration, in accordance with some embodiments.

FIG. 8B shows an example frequency control function in which the frequency of the signals that are generated by the bias RF signal generator or primary RF signal generator is substantially constant over time, in accordance with some embodiments.

FIG. 8C shows an example frequency control function in which the frequency of the signals that are generated by the bias RF signal generator or primary RF signal generator increases monotonically over time, in accordance with some embodiments.

FIG. 8D shows an example frequency control function in which the frequency of the signals that are generated by the bias RF signal generator or primary RF signal generator decreases monotonically over time, in accordance with some embodiments.

FIG. 8E shows an example frequency control function in which the frequency of the signals that are generated by the bias RF signal generator or primary RF signal generator varies in a non-linear manner over time, in accordance with some embodiments.

FIG. 9 shows an example arrangement of an RF signal generation system that implements dual DC power supplies for RF pulse-initiation power spike generation, in accordance with some embodiments.

FIG. 10 shows a diagram of the voltage output by the first DC voltage supply as a function of time to generate the RF power pulse profile of FIG. 4, in accordance with some embodiments.

FIG. 11 shows a diagram of the voltage output by the second DC voltage supply as a function of time to generate the RF power pulse profile of FIG. 4, in accordance with some embodiments.

FIG. 12 shows a diagram of the sum of the voltages output by the first DC voltage supply and the second DC voltage supply as a function of time to generate the RF power pulse profile of FIG. 4, in accordance with some embodiments.

FIG. 13 shows a diagram of the activation of the RF signal generator as a function of time to generate the RF power pulse profile of FIG. 4, in accordance with some embodiments.

FIG. 14 shows a flowchart of a method for controlling a plasma within a plasma processing chamber, in accordance with some embodiments.

FIG. 15 shows a flowchart of a method for controlling a plasma within a plasma processing chamber, in accordance with some embodiments.

### DETAILED DESCRIPTION

In the following description, numerous specific details are set forth in order to provide an understanding of embodiments of the present disclosure. It will be apparent, however, to one skilled in the art that embodiments of the present disclosure may be practiced without some or all of these specific details. In other instances, well known process operations have not been described in detail in order not to unnecessarily obscure the present disclosure.

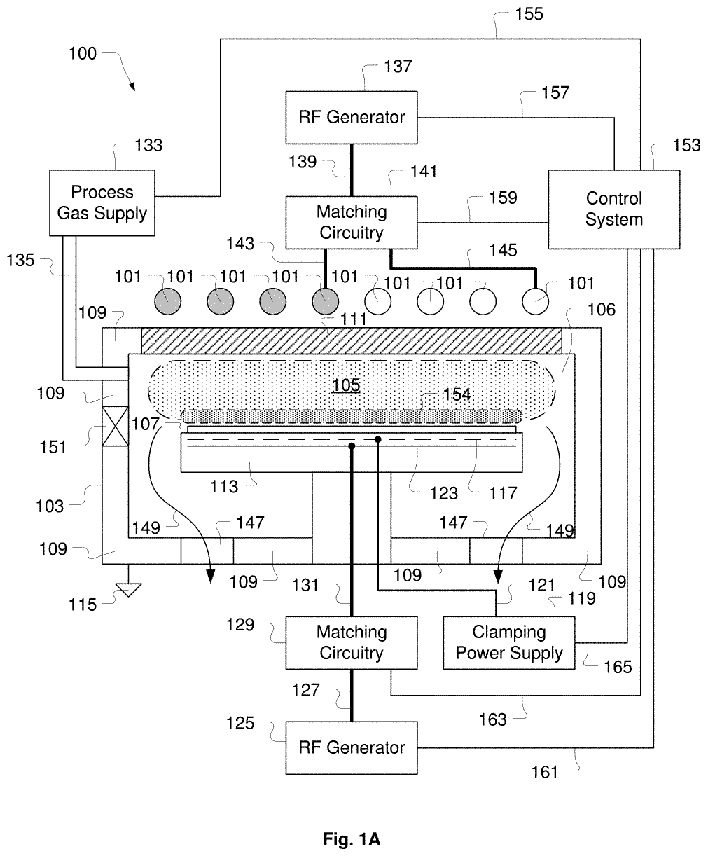

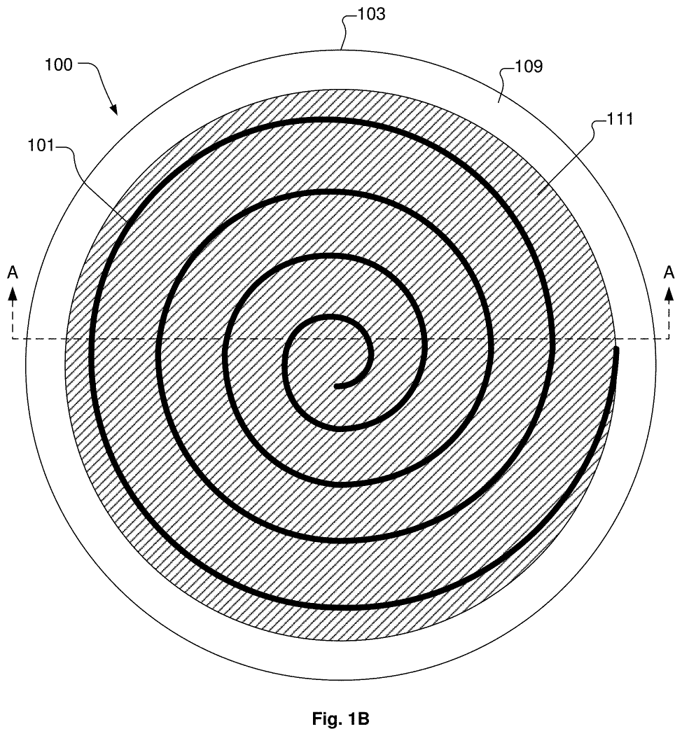

FIG. 1A shows a vertical cross-section view of a plasma processing system 100 for use in manufacturing semiconductor wafers, in accordance with some embodiments. FIG. 1B shows a top view of the plasma processing system of FIG. 1A, in accordance with some embodiments. The vertical cross-section view of FIG. 1A is referenced as View A-A in FIG. 1B. In the semiconductor industry, semiconductor substrates can undergo fabrication operations in an inductively coupled plasma (ICP) plasma processing chamber, such as the plasma processing system 100. The ICP processing chamber can also be referred to as a transformer coupled plasma (TCP) processing chamber. For ease of discussion herein, the ICP processing chamber will be used to refer to both ICP and TCP processing chambers. It should be understood that the plasma processing system 100 represents essentially any type of ICP processing chamber in which RF signals are transmitted from a coil 101 disposed outside a processing chamber 103 to a process gas within the processing chamber 103 to generate a primary plasma 105 within a plasma processing volume 106 of the processing chamber 103, where the primary plasma 105 is used to affect a change in a condition of a substrate 107 held in exposure to constituents of the primary plasma 105. FIG. 1A shows the coil 101 from which RF signals are transmitted into the plasma processing volume 106 to generate the primary plasma 105 within the plasma processing volume 106 in exposure to a substrate 107. The coil 101 is also referred to as a primary electrode.

In some embodiments, the substrate 107 is a semiconductor wafer undergoing a fabrication procedure. However, it should be understood that in various embodiments, the substrate 107 can be essentially any type of substrate that is subjected to a plasma-based fabrication process. For example, in some embodiments, the term substrate 107 as used herein can refer to substrates formed of sapphire, GaN, GaAs or SiC, or other substrate materials, and can include glass panels/substrates, metal foils, metal sheets, polymer materials, or the like. Also, in various embodiments, the substrate 107 as referred to herein may vary in form, shape, and/or size. For example, in some embodiments, the substrate 107 referred to herein may correspond to a 200 mm (millimeters) semiconductor wafer, a 300 mm semiconductor wafer, or a 450 mm semiconductor wafer. Also, in some embodiments, the substrate 107 referred to herein may correspond to a non-circular substrate, such as a rectangular substrate for a flat panel display, or the like, among other shapes.

The plasma processing volume 106 of the processing chamber 103 is formed within a surrounding structure 109 and below an upper window structure 111 and above a substrate support structure 113. In some embodiments, the surrounding structure 109 is formed of an electrically conductive material, such as a metal, that is mechanically and chemically compatible with the environment and materials present within the plasma processing volume 106 during operation of the plasma processing system 100. In these embodiments, the surrounding structure 109 can be electrically connected to a reference ground potential 115. The processing chamber 103 includes a door 151 through which the substrate 107 can be moved into and removed from the plasma processing volume 106.

The substrate support structure 113 is configured to support the substrate 107 in a secure manner in exposure to the primary plasma 105 generated within the plasma processing volume 106. In some embodiments, the substrate support structure 113 is an electrostatic chuck that includes one or more clamp electrode(s) 117 to which electric power can be supplied by a clamping power supply 119 through an electrical connection 121. The electric power supplied to the one or more clamp electrode(s) 117 generates an electrostatic field for clamping the substrate 107 onto the substrate support structure 113. In various embodiments, the clamping power supply 119 can be configured to supply either RF power, direct current (DC) power, or a combination of both RF power and DC power to the one or more clamp electrode(s) 117. In the embodiments in which the clamping power supply 119 is configured to supply RF power, the clamping power supply 119 further includes an impedance matching circuit through which the RF power is transmitted to ensure that the RF power is not unacceptably reflected from the one or more clamp electrode(s) 117. In these embodiments, the impedance matching circuit within the clamping power supply 119 includes an arrangement of capacitors and/or inductors.

The substrate support structure 113 can also include a bias electrode 123 to which RF bias power can be supplied to generate a bias voltage (V_{b}) at the substrate 107 level within the plasma processing volume 106. The RF power transmitted from the bias electrode 123 into the plasma processing volume 106 is referred to as the bias RF power. In some embodiments, the bias RF power is generated by a bias RF signal generator 125 and is transmitted through an electrical connection 127 to an impedance matching circuit 129, and then transmitted from the impedance matching circuit 129 through a transmission rod 131 to the bias electrode 123. The transmission rod 131 is electrically insulated from the surrounding structure 109 of the processing chamber 103. The impedance matching circuit 129 includes an arrangement of capacitors and/or inductors configured to ensure that an impedance seen by the bias RF signal generator 125 at the transmission rod 131 is sufficiently close to a load impedance for which the bias RF signal generator 125 is designed to operate, so that RF signals generated and transmitted by the bias RF signal generator 125 will be transmitted into the plasma processing volume 106 in an efficient manner, i.e., without unacceptable reflection.

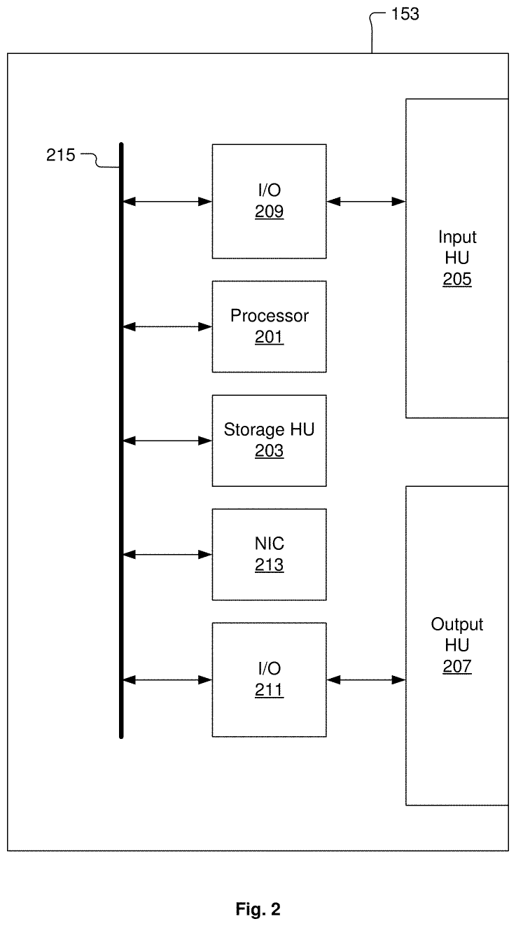

The plasma processing system 100 operates by flowing one or more process gases from a process gas supply 133 through an arrangement of fluid conveyance structures 135 into the plasma processing volume 106, and by applying RF power from the coil 101 to the one or more process gases to transform the one or more process gases into the primary plasma 105 in exposure to the substrate 107, in order to affect a change in material or surface condition on the substrate 107. The used process gases and other materials that result from processing of the substrate 107 are exhausted from the plasma processing volume 106 through one or more exhaust ports 147, as indicated by the arrows 149. The coil 101 is disposed above the upper window structure 111. In the example of FIGS. 1 and 2, the coil 101 is formed as a radial coil assembly, with the shaded parts of the coil 101 turning into the page of the drawing and with the unshaded parts of the coil 101 turning out of the page of the drawing. FIG. 1B shows a top view of the example coil 101 of FIG. 1A, in accordance with some embodiments of the present invention. It should be understood, however, that in other embodiments the coil 101 can be of essentially any configuration that is suitable for transmitting RF power through the upper window structure 111 and into the plasma processing volume 106. In various embodiments, the coil 101 can have any number of turns and any cross-section size and shape (circular, oval, rectangular, trapezoidal, etc.) as required to provide the necessary transmission of RF signals through the upper window structure 111 into the plasma processing volume 106.

Also, in some embodiments, a return electrical connection 145 extends from the coil 101 to the matching circuitry 141.

The RF power transmitted from the coil 101 into the plasma processing volume 106 is referred to as the plasma primary RF power. The plasma primary RF power is generated by a primary RF signal generator 137 and is transmitted through an electrical connection 139 to an impedance matching circuit 141, and through an electrical connection 143 to the coil 101. The matching circuit 141 includes an arrangement of capacitors and/or inductors configured to ensure that an impedance seen by the primary RF signal generator 137 at the coil 101 is sufficiently close to a load impedance for which the primary RF signal generator 137 is designed to operate, so that RF signals supplied to the coil 101 by the primary RF signal generator 137 will be transmitted into the plasma processing volume 106 in an efficient manner without unacceptable reflection.

It should be understood that the coil 101 of FIGS. 1 and 2 is presented by way of example. In some embodiments, the coil 101 can include multiple zones, with each zone spanning a specified corresponding radial extent above the upper window structure 111. In these embodiments, the RF power supplied to each zone of the coil 101 is independently controlled. Also, it should be understood that the number of turns (about the center of the upper window structure 111) of the example coil 101 of FIGS. 1 and 2 is presented by way of example. In various embodiments, the coil 101 can have any number of turns and any cross-section size and shape (circular, oval, rectangular, trapezoidal, etc.) as required to provide the necessary transmission of RF signals through the upper window structure 111 into the plasma processing volume 106.

The plasma processing system 100 has certain advantages in plasma process control in various plasma-based semiconductor fabrication applications, such as in plasma etching, by way of example. The plasma processing system 100 provides for separate control of plasma density (ion flux/radical flux) and ion energy. Specifically, the plasma density can be controlled to a certain extent by the plasma primary RF power that is transmitted from the coil 101 through the upper window structure 111 into the plasma processing volume 106. And, the ion energy can be controlled by the bias voltage (V_{b}) that is generated at the substrate level by the bias RF power transmitted from the bias electrode 123 into the plasma processing volume 106. Separate control of plasma density (which directly correlates to ion flux and radical flux) and ion energy is particularly useful in some semiconductor fabrication applications. For example, in patterning applications where high plasma density is needed to obtain a required etch rate and where low ion energy is required to reduce damage to one or more materials present on the substrate, such as photoresist material. It should be understood that in addition to patterning applications, many other plasma-based semiconductor fabrication applications can also benefit from separate control of plasma density and ion energy.

With the plasma processing system 100, the plasma density can be increased through control of the plasma primary RF power supplied to the coil 101, and the bias voltage (V_{b}) can be controlled through control of the bias RF power supplied to the bias electrode 123. Also, the plasma primary RF power/frequency and the bias RF power/frequency may need to be controlled in different ways at the same time to achieve a desired result. For example, in some embodiments, to obtain increased plasma density in conjunction with low ion energy, the plasma primary RF power needs to be high and at the same time the bias RF power needs to be low.

In some fabrication applications a high density plasma is needed at the substrate 107 level to obtain an increased ion flux and/or increased radical flux near the substrate 107 to obtain an increased interaction rate on the substrate 107, and simultaneously, a low ion energy is required at the substrate 107 level to avoid damage to material on the substrate 107 and/or to reduce directionality of the ion flux incident upon the substrate 107, i.e., to have a more isotropic ion flux at the substrate 107 level. In these fabrication applications, the plasma density needs to be increased at the substrate 107 level without increasing the bias voltage (V_{b}) at the substrate 107 level. For example, in a patterning application, a photoresist material can be used to provide a protective coating over portions of the substrate 107 during an etching operation. In this situation, a high bias voltage (V_{b}) can increase the ion energy to the point where the ions that are incident upon the photoresist material will sputter the photoresist material off of the substrate 107. And, because it is necessary for the photoresist material to remain through the entirety of the etching process, it is of interest to keep the bias voltage (V_{b}) at the substrate 107 level low, e.g., less than 200 V (volts), to avoid sputtering of the photoresist material and premature loss of the photoresist material.

In some situations, the plasma primary RF power transmitted from the coil 101 through the upper dielectric window 111 into the plasma processing volume 106 does not provide enough plasma density at the substrate 107 level to obtain a necessary etch rate and/or etch selectivity. One reason for this is that the density of the primary plasma 105 generated by the plasma primary RF power transmitted from the coil 101 decreases with increased distance from the coil 101. Therefore, with increased distance between the coil 101 and the substrate support structure 113, it becomes more difficult to obtain a required plasma density at the substrate 107 level. Also, the lower frequency of the bias RF power that is applied to the bias electrode 123 generates a DC bias voltage (V_{b}) on the substrate 107 without contributing much to the plasma density near the substrate 107. Additionally, it may not be possible to simply increase the plasma primary RF power supplied to the coil 101 beyond a specified maximum amount, such as about 3 kW (kiloWatts), due to potential damage caused by overheating of the upper window structure 111. Also, reducing the distance between the coil 101 and substrate support structure 113 may require a costly redesign of the processing chamber 103, and potentially cause problems with regard to plasma uniformity at the substrate 107 level, and present other challenges.

It is possible to provide an increase in plasma density at the substrate 107 level without causing an increase in ion energy at the substrate 107 level. The bias electrode 123 can be used to transmit specially controlled RF signals into the plasma processing volume 106 to generate supplemental plasma density 154 locally at the substrate 107 level. And, in some embodiments, it is possible to generate the supplemental plasma density 154 locally at the substrate 107 level without increasing the ion energy at the substrate 107 level. The bias RF power applied at the substrate 107 level by the bias RF signal generator 125 is controlled to generate the supplemental plasma density 154 at the substrate 107 level, i.e., just above the substrate 107. Generally, the bias voltage (V_{b}) generated by the RF signals supplied by the bias RF signal generator 125 is inversely proportional to the frequency (ƒ) of these RF signals (V_{b}∝1/ƒ). Because the bias RF power (P_{b}) is given by the product of the bias voltage (V_{b}) and the bias current (I_{b}), i.e., (P_{b}=V_{b}*I_{b}), when the bias voltage (V_{b}) is lower, the bias current (I_{b}) has to be correspondingly higher to have the same bias RF power (P_{b}). Therefore, to achieve a higher plasma density from a given bias RF power (P_{b}), it is necessary to have a lower bias voltage (V_{b}) and a correspondingly higher bias current (I_{b}). And, because the bias voltage (V_{b}) is inversely proportional to the frequency (ƒ) of the bias RF signals, in order to obtain a lower bias voltage (V_{b}) for a given bias RF power (P_{b}), the frequency (ƒ) of the bias RF signals can be increased. Therefore, to obtain an increase in the supplemental plasma density 154 generated at the substrate 107 level, while simultaneously keeping the bias voltage (V_{b}) low, RF signals of higher frequency (ƒ) can be supplied to the bias electrode 123.

At the substrate 107 level, the effective plasma density is the sum of the plasma density generated by the plasma primary RF power and the plasma density generated by the RF signals supplied to the bias electrode 123. In some embodiments where a higher plasma density is needed at the substrate 107 level without increasing the ion energy at the substrate 107 level, a supplemental plasma density 154 RF power is supplied to the bias electrode 123 at a high frequency (e.g., greater than or equal to about 27 MHz (megaHertz)) to generate supplemental plasma density 154 at the substrate 107 level with low bias voltage (V_{b}) (e.g., less than about 200 V), and a bias RF power is also supplied to the bias electrode 123 at a low frequency (e.g., less than or equal to about 15 MHz) to provide control of the bias voltage (V_{b}), and a plasma primary RF power is supplied to the coil 101 to generate the primary plasma 105 within the plasma processing volume 106.

The plasma processing system 100 also includes a control system 153 configured and connected to control operations of the plasma processing system 100. The control system 153 is configured and connected through a connection 155 to control the process gas supply 133. The control system 153 is configured and connected through a connection 157 to control the primary RF signal generator 137. The control system 153 is configured and connected through a connection 159 to control the impedance matching circuit 141. The control system 153 is configured and connected through a connection 161 to control the bias RF signal generator 125. The control system 153 is configured and connected through a connection 163 to control the impedance matching circuit 129. The control system 153 is configured and connected through a connection 165 to control the clamping power supply 119. It should be understood that in various embodiments, any of the connections 155, 157, 159, 161, 163, and 165 can be either a wired connection, a wireless connection, an optical connection, or a combination thereof. It should be understood that in various embodiments, the control system 153 can be configured and connected to control essentially any feature of the plasma processing system 100 that lends itself to active control. Also, it should be understood that in various embodiments, the control system 153 is configured and connected to various metrology and sensors and other data acquisition devices disposed throughout the plasma processing system 100 to measure and monitor any and all parameters that are relevant to operation of the plasma processing system 100. Also, in various embodiments, data/signal connection between the control system 153 and the various metrology and sensors and other data acquisition devices can be either a wired connection, a wireless connection, an optical connection, or a combination thereof.

FIG. 2 shows an example arrangement of the control system 153, in accordance with some embodiments. In various embodiments, the control system 153 includes a processor 201, a storage hardware unit (HU) 203 (e.g., computer memory), an input HU 205, an output HU 207, an input/output (I/O) interface 209, an I/O interface 211, a network interface controller (NIC) 213, and a data communication bus 215. The processor 201, the storage HU 203, the input HU 205, the output HU 207, the I/O interface 209, the I/O interface 211, and the NIC 213 are in data communication with each other by way of the data communication bus 215.

The input HU 205 is configured to receive data communication from a number of external devices, such as from the process gas supply 133, the primary RF signal generator 137, the impedance matching circuit 141, the bias RF signal generator 125, the impedance matching circuit 129, the clamping power supply 119, and/or any other device within the plasma processing system 100. Examples of the input HU 205 include a data acquisition system, a data acquisition card, etc. The output HU 207 is configured to transmit data to a number of external devices, such as to the process gas supply 133, the primary RF signal generator 137, the impedance matching circuit 141, the bias RF signal generator 125, the impedance matching circuit 129, the clamping power supply 119, and/or any other device within the plasma processing system 100. An example of the output HU 207 is a device controller. Examples of the NIC 213 include a network interface card, a network adapter, etc. Each of the I/O interfaces 209 and 211 is defined to provide compatibility between different hardware units coupled to the I/O interface. For example, the I/O interface 209 can be defined to convert a signal received from the input HU 205 into a form, amplitude, and/or speed compatible with the data communication bus 215. Also, the I/O interface 211 can be defined to convert a signal received from the data communication bus 215 into a form, amplitude, and/or speed compatible with the output HU 207. Although various operations are described herein as being performed by the processor 201 of the control system 153, it should be understood that in some embodiments various operations can be performed by multiple processors of the control system 153 and/or by multiple processors of multiple computing systems in data communication with the control system 153. Also, in some embodiments, there is a user interface associated with the control system 153. The user interface may include a display (e.g., a display screen and/or graphical software displays of the apparatus and/or process conditions) and user input devices such as pointing devices, keyboards, touch screens, microphones, etc.

The control system 153 can be configured to execute computer programs including sets of instructions for controlling operation of the process gas supply 133, the primary RF signal generator 137, the impedance matching circuit 141, the bias RF signal generator 125, the impedance matching circuit 129, the clamping power supply 119, and/or any other controllable device within the plasma processing system 100. Also, computer programs stored on memory devices associated with the control system 153 may be employed in some embodiments. Software for directing operation of the control system 153 may be designed or configured in many different ways. Computer programs for directing operation of the control system 153 to in turn direct operation of the plasma processing system 100 can be written in any conventional computer readable programming language: for example, assembly language, C, C++, Pascal, Fortran or others. Compiled object code or script is executed by the processor 201 to perform the tasks identified in the program.

Generally speaking, the control system 153 is defined as electronics having various integrated circuits, logic, memory, and/or software that receive instructions, issue instructions, and control operations. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the control system 153 in the form of various individual settings (or program files), defining operational parameters for operating the plasma processing system 100 to carrying out a prescribed process on the substrate 107.

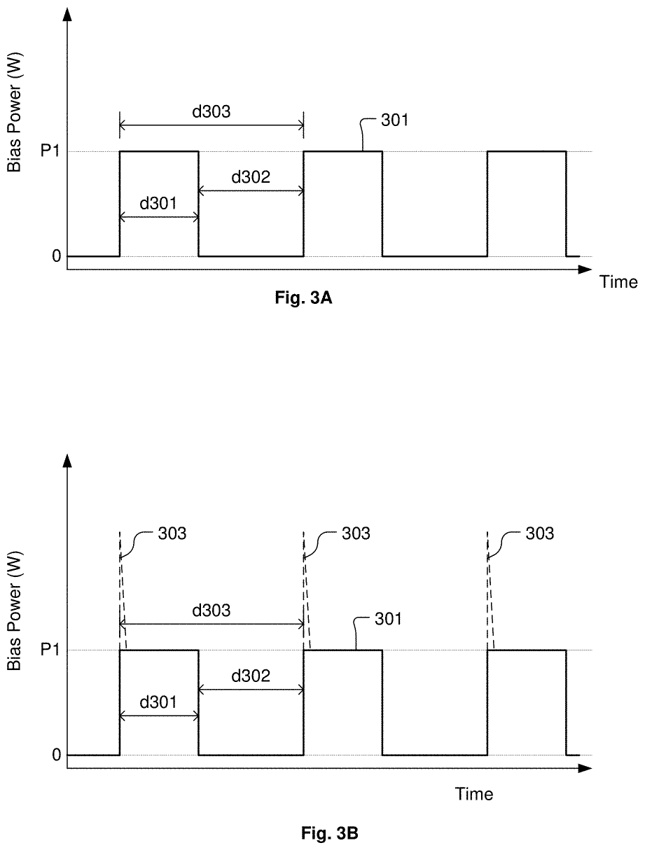

In conductor etch applications where the primary plasma 105 chemistry is highly electronegative and a high bias voltage (V_{b}) is supplied in a pulsed manner, it is very difficult to push out and stabilize the plasma 105 sheath when the bias RF signal generator 125 is turned on to supply RF power to the bias electrode 123. FIG. 3A shows a square-shaped RF power pulse profile 301 that may be supplied by the bias RF signal generator 125 to the bias electrode 123 to generate the bias voltage (V_{b}), in accordance with some embodiments. The square-shaped RF power pulse profile 301 includes a series of pulses of RF power in accordance with a set cycle duration d303. Each pulse of RF power has an essentially square shape. Each pulse of RF power goes from a power level of about zero to a power level P1. Each pulse of RF power has a pulse duration d301. The duration between successive RF power pulses is an interpulse duration d302. During each interpulse duration d302, the RF power goes from a power level of P1 to a lower power level (e.g., to a power of about zero). The set cycle duration d303 is the sum of the pulse duration d301 and the interpulse duration d302.

Use of the square-shaped RF power pulse profile 301 as shown in FIG. 3A presents a timing problem, because the process of getting RF energy into the plasma 105 starts slowly and takes time to complete. Consider that there is a significant change in the impedance of the plasma processing volume 106 between having the plasma 105 present therein and not having the plasma 105 present, or rather one may say between having a plasma 105 sheath and not having a plasma 105 sheath. Further consider that there are heavy ions within the plasma 105 that have to be pushed away from the bias electrode 123 in order to stabilize the plasma 105 sheath. It takes a significant amount of energy and time to move these heavy ions. At the beginning of an RF power pulse, the bias RF signal generator 125 and corresponding impedance matching circuit 129 will operate as though they are pushing RF power into the plasma 105 sheath, because that is the last thing they were doing at the end of the previous RF power pulse. However, at the beginning of each RF power pulse, the bias RF signal generator 125 and corresponding impedance matching circuit 129 are actually pushing RF power into a badly mismatched load. Therefore, at the beginning of the RF power pulse, not much RF power can be pushed from the bias RF signal generator 125 and corresponding impedance matching circuit 129 into the plasma 105. It is a slow process to get RF power into the plasma 105 at the beginning of the RF power pulse, because the RF energy initially enters the plasma 105 at a slow rate due to impedance mismatch, and then as the plasma 105 sheath begins to build in, the bias RF signal generator 125 and corresponding impedance matching circuit 129 become impedance tuned to allow more and more RF energy to enter the plasma 105.

Therefore, the process of getting RF energy from the bias RF signal generator 125 and corresponding impedance matching circuit 129 into the plasma 105 during a square-shaped RF power pulse starts slowly and takes time to complete. For this reason, in certain applications, such as in conductor etch applications where the primary plasma 105 chemistry is highly electronegative and high bias voltage (V_{b}) is supplied in a pulsed manner, the square-shaped RF power pulse profile 301 may not be usable. Instead, what is needed is a high amplitude, short duration RF power spike at the start of each RF pulse in order to quickly establish and stabilize the plasma 105 sheath near the bias electrode 123. In some cases, without such a high amplitude, short duration RF power spike at the start of each RF pulse, the plasma 105 sheath will not stabilize over the RF power pulse duration d301.

The bias RF signal generator 125 has an initial masking time when the bias RF signal generator 125 operates in an open loop control mode. During this initial masking time, there can be a naturally large initial spike of RF power, depending on the cabling configuration, the operating frequency of the bias RF signal generator 125, and the impedance seen by the bias

RF signal generator 125. FIG. 3B shows the square-shaped RF power pulse profile 301 of FIG. 3A, with an initial spike of RF power 303 associated with the initial masking time of the bias RF signal generator 125, in accordance with some embodiments. More specifically, at the beginning of each square-shaped pulse of RF power, an initial spike of RF power 303 occurs due the bias RF signal generator 125 operating in the open loop control mode. After the initial spike of RF power 303, the RF power settles to the power level P1 set for the RF power pulse profile 301. The magnitude and duration of the initial spike of RF power 303 is dependent upon the cabling configuration (between the bias RF signal generator 125 and the impedance matching circuit 129, and between the impedance matching circuit 129 and the bias electrode 123), the operating frequency of the bias RF signal generator 125, the impedance seen by the bias RF signal generator 125, and the chemistry of the plasma 105. It should be understood that the initial spike of RF power 303 at the beginning of each RF power pulse is not controlled. Therefore, although the initial spike of RF power 303 can be helpful in accelerating the establishment and stabilization of the plasma 105 sheath at the beginning of each RF power pulse, the initial spike of RF power 303 cannot be relied upon for that purpose.

In some embodiments, an attempt is made to maximize the initial spike of RF power 303 that occurs due to the natural response to the bias RF signal generator 125 operating in open loop control mode. More specifically, an example approach includes finding a particular cable length and/or a particular frequency setpoint of the bias RF signal generator 125 that will cause the impedance that the bias RF signal generator 125 sees at the instant of the start of the

RF power pulse to be where the RF power output is the highest, with the bias RF signal generator 125 operating in the natural open loop control mode. For example, a certain cabling configuration and setpoint frequency of the bias RF signal generator 125 can be determined to maximize the initial spike of RF power 303. This approach can cause the initial spike of RF power 303 to be several times higher than the actual power level (P1) setpoint of the RF power pulse and can be up to two times the stated full scale power of the bias RF signal generator 125. Therefore, it should be understood that attempts to maximize the initial spike of RF power 303 with the bias RF signal generator 125 operating in open loop control mode can be dangerous and can even cause destruction of the bias RF signal generator 125. Also, the optimal cable length and/or optimal setpoint frequency can change from one substrate 107 process recipe to another, and can change with just a tweaking of some substrate 107 process recipe parameter(s). Therefore, it is of interest to develop a controlled approach for initially spiking the RF power at the beginning of each RF power pulse.

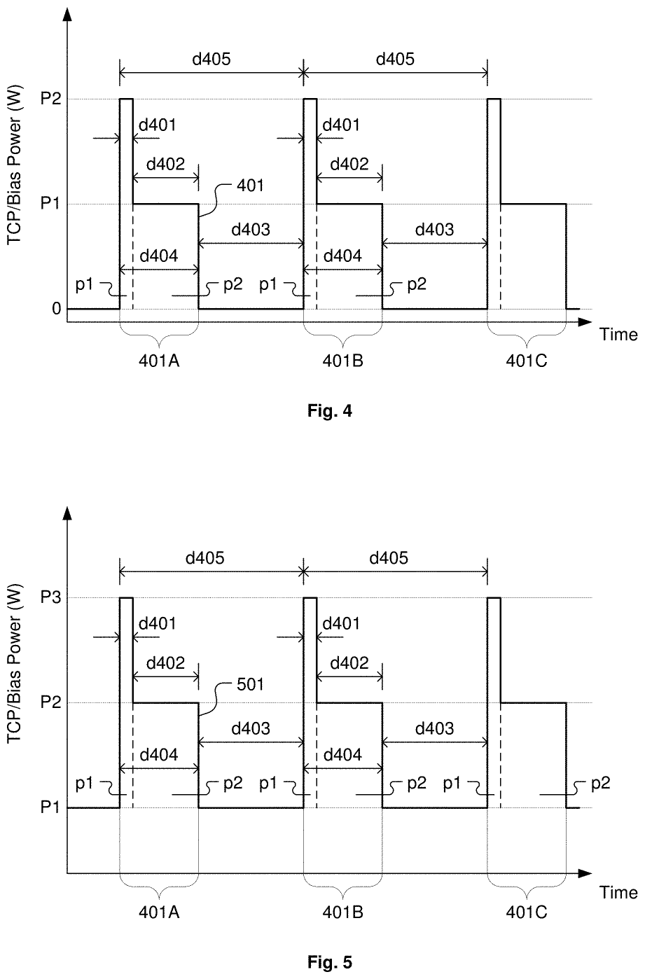

FIG. 4 shows an RF power pulse profile 401 that includes RF pulse-initiation power spiking, in accordance with some embodiments. It should be understood that the RF power pulse profile 401 can be applied equally to operation of the bias RF signal generator 125 and to operation of the primary RF signal generator 137. More specifically, when the bias RF signal generator 125 is being operated in a pulsed mode, the RF power pulse profile 401 can be used. Also, when the primary RF signal generator 137 is being operated in a pulsed mode, the RF power pulse profile 401 can be used. The RF power pulse profile 401 includes multiple, sequential pulses of RF power 401A, 401B, 401C, etc., in accordance with a set cycle duration d405. Each pulse of RF power 401A, 401B, 401C, etc., includes a first duration d401 over which a first RF power profile p1 exists, immediately followed by a second duration d402 over which a second RF power profile p2 exists. The first RF power profile p1 has a greater RF power than the second RF power profile p2. In the example of FIG. 4, the first RF power profile p1 has an RF power level of P2, and the second RF power profile p2 has an RF power level of P1. Also, the first duration d401 of the first RF power profile p1 is less than the second duration d402 of the second RF power profile p2. Each pulse of RF power 401A, 401B, 401C, etc., has a pulse duration d404, which is the sum of the duration of the first duration d401 of the first RF power profile p1 and the second duration d402 of the second RF power profile p2. Also, the sequential pulses of RF power 401A, 401B, 401C, etc., are separated from each other by a third duration d403, referred to as the interpulse duration d403. The set cycle duration d405 is the sum of the pulse duration d404 and the interpulse duration d403.

The first RF power profile p1 defines an RF pulse-initiation power spike. By way of the first RF power profile p1, the RF pulse-initiation power spike is controllable in terms of power and time. The power level P2 and duration d401 of the first RF power profile p1 is set to accelerate establishment and stabilization of the plasma 105 sheath at the beginning of each RF power pulse 401A, 401B, 401C, etc. Therefore, it should understood that the first RF power profile p1 is defined to put more RF energy into the plasma 105 at the beginning of generation of the plasma 105 (as the plasma 105 sheath initially builds in). The RF power pulse profile 401 can be used in many different plasma processing operations for semiconductor device fabrication, and is particular useful in plasma-based etching of a conductor material and/or a carbon-based hardmask material on the substrate 107.

In the example RF power pulse profile 401, the first RF power profile p1 is a substantially constant first RF power at the set power level P2, and the second RF power profile p2 is a substantially constant second RF power at the set power level P1, and during the interpulse duration d403 between successive pulses 401A, 401B, 401C, etc., the RF power is essentially zero. In some embodiments, when the bias RF signal generator 125 is operated in accordance with the RF power pulse profile 401, the impedance matching circuit 129 is optimized for the conditions present during the second RF power profile p2. In other embodiments, when the bias RF signal generator 125 is operated in accordance with the RF power pulse profile 401, the impedance matching circuit 129 is optimized for the conditions present during the first RF power profile p1. In some embodiments, when the primary RF signal generator 137 is operated in accordance with the RF power pulse profile 401, the impedance matching circuit 141 is optimized for the conditions present during the second RF power profile p2. In other embodiments, when the primary RF signal generator 137 is operated in accordance with the RF power pulse profile 401, the impedance matching circuit 141 is optimized for the conditions present during the first RF power profile p1.

In some embodiments, a sum of the first duration d401 of the first RF power profile p1 and the second duration d402 of the second RF power profile p1 and the interpulse duration d403 is less than or equal to about 10 milliseconds. Or, in other words, in some embodiments, the set cycle duration d405 is less than or equal to about 10 milliseconds. In some embodiments, a sum of the first duration d401 of the first RF power profile p1 and the second duration d402 of the second RF power profile p1 is less than one-half of the set cycle duration d405. Or, in other words, in some embodiments, the pulse duration d404 is less than one-half of the set cycle duration d405. Or, in other words, in some embodiments, a sum of the first duration d401 of the first RF power profile p1 and the second duration d402 of the second RF power profile p1 is less than the interpulse duration d403. In some embodiments, the first duration d401 of the first RF power profile p1 is within a range extending from about 10 microseconds to about 100 microseconds, or within a range extending from about 20 microseconds to about 80 microseconds, or within a range extending from about 40 microseconds to about 50 microseconds. In some embodiments, the first duration d401 of the first RF power profile p1 is about 5% to about 25% of a sum of the first duration d401 of the first RF power profile p1 and the second duration d402 of the second RF power profile p2. In some embodiments, the first duration d401 of the first RF power profile p1 is about 10% to about 15% of a sum of the first duration d401 of the first RF power profile p1 and the second duration d402 of the second RF power profile p2. In an example embodiment, the bias RF signal generator 125 is operated to provide an RF pulse-initiation power spike of about 1000 Watts for about 10 to about 100 microseconds at the beginning of each bias RF power pulse 401A, 401B, 401C, etc., followed by a steady RF bias power level of about 500 W for the remainder of each bias RF power pulse 401A, 401B, 401C, etc. In an example embodiment of the RF power pulse profile 401, the set power level P1 (of the second RF power profile p2) is 3000 Watts (W), and the set power level P2 (of the first RF power profile p1) is within a range extending from about 5000 W to about 6000 W. In another example embodiment of the RF power pulse profile 401, the set power level P1 (of the second RF power profile p2) is 500 Watts (W), and the set power level P2 (of the first RF power profile p1) is within a range extending from about 1000 W to about 2000 W. The term “about” as used herein represents plus or minus 10%. It should be understood that the above-described values for the set power levels P1 and P2 of the RF power pulse profile 401 are provided by way of example. In other embodiments of the RF power pulse profile 401, the set power levels P1 and P2 are set as needed, such as to achieve a desired plasma control effect, or other result.

The rail voltage supply for the bias RF signal generator 125 or the primary RF signal generator 137 mainly controls the absolute amount of maximum RF power that can be output. An additional amount of rail voltage can be provided to the bias RF signal generator 125 or the primary RF signal generator 137 at the beginning of the RF power pulse 401A, 401B, 401C, etc., to generate the RF pulse-initiation power spike in accordance with the first RF power profile p1. In some embodiments, the additional amount of rail voltage used to generate the RF pulse-initiation power spike at the beginning of each RF power pulse 401A, 401B, 401C, etc., is provided by an additional voltage supply device (DC power supply) connected within the bias RF signal generator 125 or the primary RF signal generator 137, as the case may be. In some embodiments, the additional voltage supply device can be switchably connected to the rail voltage supply for the bias RF signal generator 125 or the primary RF signal generator 137 to provide temporal control of the rail voltage supply in order to comply with the first RF power profile p1.

In addition to having the additional voltage supply device, the output of the extant rail voltage supply for the bias RF signal generator 125 or the primary RF signal generator 137 can be increased during the first RF power profile p1 to give a small boost in power. But, the amount of power added by increasing the output of the extant rail voltage supply for the bias RF signal generator 125 or the primary RF signal generator 137 is less than what is needed and is less than what is provided by the additional voltage supply device. Also, in some embodiments, during the first RF power profile p1, the power limits can be fully removed from the bias RF signal generator 125 or the primary RF signal generator 137 to create an “ignition state” in which the RF generator is allowed to frequency tune in order to reduce reflected power with maximum power output.

The RF power pulse profile 401 of FIG. 4 represents single-level RF power pulsing in which the RF power is pulsed between zero and a set power level P1, with the first RF power profile p1 having the set power level P2. FIG. 5 shows an RF power pulse profile 501 that represents dual-level RF power pulsing in which the RF power is pulsed between a first set non-zero power level P1 and a set power level P2, with the first RF power profile p1 having the set power level P3, in accordance with some embodiments. In the dual-level RF power pulsing of FIG. 5, the RF power during the third duration (interpulse duration) d403 is a substantially constant RF power level P1 that is greater than zero. In an example embodiment of the RF power pulse profile 501, the set power level P1 (of the interpulse duration d403) is 500 W, and the set power level P2 (of the second RF power profile p2) is 3000 W, and the set power level P3 (of the first RF power profile p1) is within a range extending from about 5000 W to about 6000 W. In an example embodiment of the RF power pulse profile 501, the set power level P1 (of the interpulse duration d403) is 100 W, and the set power level P2 (of the second RF power profile p2) is 500 W, and the set power level P3 (of the first RF power profile p1) is within a range extending from about 1000 W to about 2000 W. It should be understood that the above-described values for the set power levels P1, P2, and P3 of the RF power pulse profile 501 are provided by way of example. In other embodiments of the RF power pulse profile 501, the set power levels P1, P2, and P3 are set as needed, such as to achieve a desired plasma control effect, or other result.

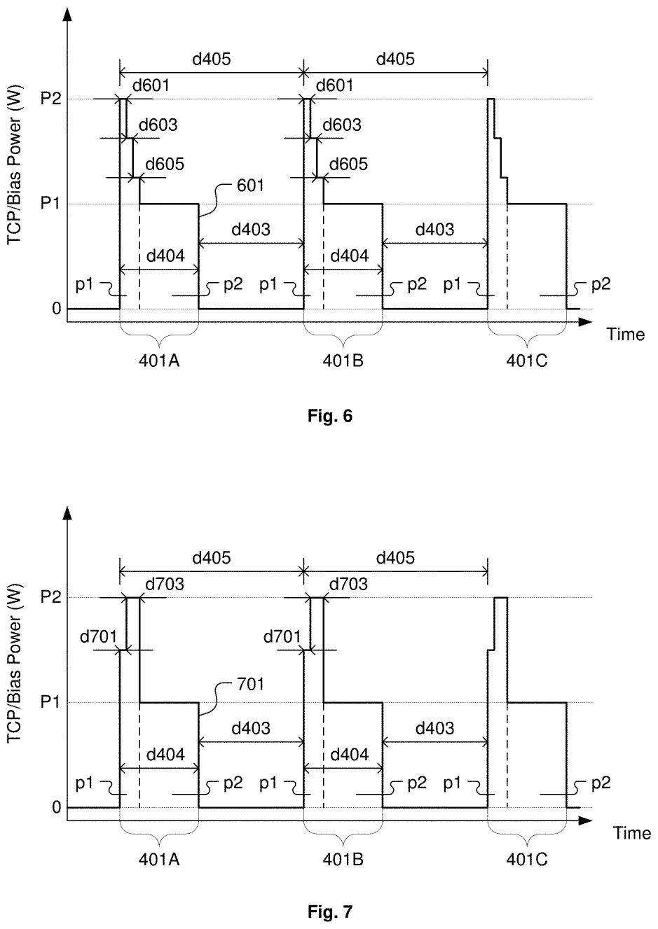

In the RF power pulse profile 401 of FIG. 4, the first RF power profile p1 has a substantially constant RF power level P2. However, in some embodiments, the first RF power profile p1 can be non-constant, i.e., can vary as a function of time. FIG. 6 shows an RF power pulse profile 601 that represents single-level RF power pulsing in which the RF power is pulsed between zero and a set power level P1, with a first RF power profile p1 that exceeds the set power level P1 and is non-constant, in accordance with some embodiments. The RF power pulse profile 601 is essentially the same as the RF power pulse profile 401, with the exception of the first RF power profile p1. The first RF power profile p1 of the RF power pulse profile 601 initially jumps to the power level P2, then decreases over time from the power level P2 to the power level P1. Specifically, the first RF power profile p1 of the RF power pulse profile 601 decreases in three steps over time to go from the power level P2 to the power level P1, where a first step extends over a duration d601, a second step extends over a duration d603, and a third step extends over a duration d605.

Also, in some embodiments, the first RF power profile p1 can increase as a function of time. FIG. 7 shows an RF power pulse profile 701 that represents single-level RF power pulsing in which the RF power is pulsed between zero and a set power level P1, with a first RF power profile p1 that exceeds the set power level P1 and is non-constant, in accordance with some embodiments. The RF power pulse profile 701 is essentially the same as the RF power pulse profile 401, with the exception of the first RF power profile pl. The first RF power profile p1 of the RF power pulse profile 701 increases in steps to reach the power level P2. Specifically, the first RF power profile p1 of the RF power pulse profile 701 increases in two steps over time to go from a zero power level to the power level P2, where a first step extends over a duration d701, and a second step extends over a duration d703. It should be understood that the RF power pulse profiles 601 and 701 of FIGS. 6 and 7, respectively, are provided by way of example. In various embodiments, the first RF power profile p1 that defines the RF pulse-initiation power spike can be configured in essentially anyway needed to most efficiently and/or rapidly establish and stabilize the plasma 105 sheath.

In some embodiments, the frequency of the signals that are generated by the bias RF signal generator 125 or primary RF signal generator 137 is a constant during an entirety of the pulse duration d404. More specifically, in some embodiments, the frequency of the signals that are generated by the bias RF signal generator 125 or primary RF signal generator 137 is the same during both the duration d401 of the first RF power profile p1 corresponding to the RF pulse-initiation power spike and the duration d402 of the second RF power profile p2 corresponding to the settled pulse power level. However, in some embodiments, the frequency of the signals that are generated by the bias RF signal generator 125 or primary RF signal generator 137 is varied during the pulse duration d404. In this manner, the frequency of the signals that are generated by the bias RF signal generator 125 or primary RF signal generator 137 can be optimized for RF power delivery to the plasma 105. For example, consider that the impedance of the plasma 105 during the first duration d401 of the first RF power profile p1 may be different than the impedance of the plasma 105 during the second duration d402 of the second RF power profile p2. With this consideration, the frequency of the signals that are generated by the bias RF signal generator 125 or primary RF signal generator 137 can be controlled in a first manner during the first duration d401 of the first RF power profile p1, and can be controlled in a second manner during the second duration d402 of the second RF power profile p2, to optimize RF power delivery to the plasma 105 during the entire pulse duration d404.

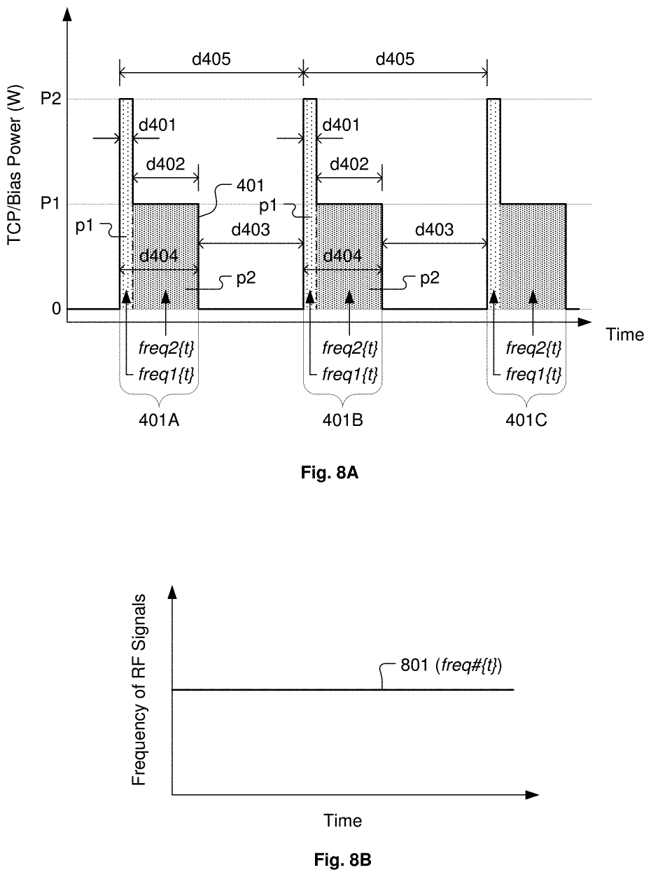

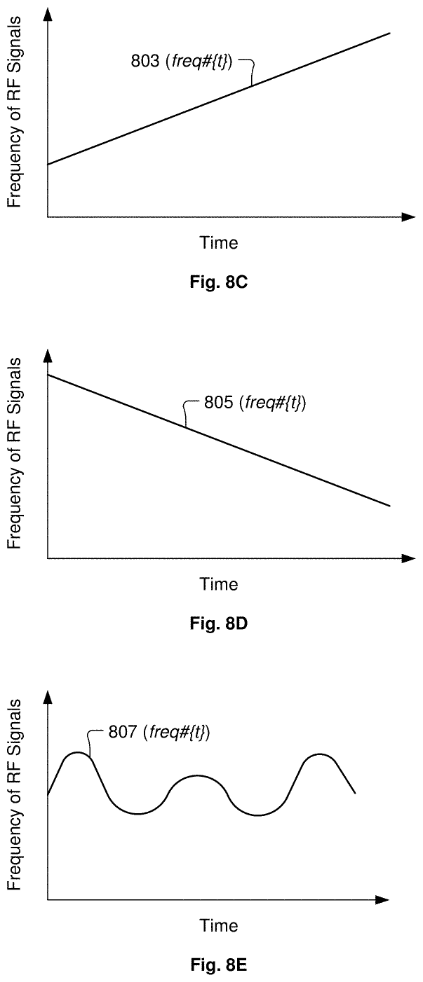

FIG. 8A shows the RF power pulse profile 401 of FIG. 4 with frequency variation applied over the pulse duration d404, in accordance with some embodiments. In the example of FIG. 8A, the frequency of the signals that are generated by the bias RF signal generator 125 or primary RF signal generator 137 during the first duration d401 of the first RF power profile p1 correspond to a first frequency control function freq1{t}. And, the frequency of the signals that are generated by the bias RF signal generator 125 or primary RF signal generator 137 during the second duration d402 of the second RF power profile p2 correspond to a second frequency control function freq2{t}. Each of the first frequency control function freq1{t} and the second frequency control function freq2{t} is essentially a specification of frequency setpoint as a function of time for the bias RF signal generator 125 or primary RF signal generator 137. In some embodiments, the frequency of the bias RF signal generator 125 or primary RF signal generator 137 can be changed/adjusted within a time of less than or equal to about 1 microsecond. Therefore, a frequency tuning resolution of each of the first frequency control function freq1{t} and the second frequency control function freq2{t} is less than or equal to about 1 microsecond.

The first frequency control function freq1{t} and the second frequency control function freq2{t} can be defined independently of each other, and can be either the same or different. In some embodiments, the first frequency control function freq1{t} and/or the second frequency control function freq2{t} can be a linear function with respect to time. FIG. 8B shows an example frequency control function 801 (freq#{t}) in which the frequency of the signals that are generated by the bias RF signal generator 125 or primary RF signal generator 137 is substantially constant over time, in accordance with some embodiments. The frequency control function 801 (freq#{t}) is representative of the first frequency control function freq1{t} and/or the second frequency control function freq2{t}.

FIG. 8C shows an example frequency control function 803 (freq#{t}) in which the frequency of the signals that are generated by the bias RF signal generator 125 or primary RF signal generator 137 increases monotonically over time, in accordance with some embodiments. The frequency control function 803 (freq#{t}) is representative of the first frequency control function freq1{t} and/or the second frequency control function freq2{t}. In some embodiments, the frequency control function 803 (freq#{t} is a linear function, such as shown in FIG. 8C. However, in other embodiments, the frequency control function 803 (freq#{t}) is a monotonically increasing non-linear function.

FIG. 8D shows an example frequency control function 805 (freq#{t}) in which the frequency of the signals that are generated by the bias RF signal generator 125 or primary RF signal generator 137 decreases monotonically over time, in accordance with some embodiments. The frequency control function 805 (freq#{t}) is representative of the first frequency control function freq1{t} and/or the second frequency control function freq2{t}. In some embodiments, the frequency control function 805 (freq#{t}) is a linear function, such as shown in FIG. 8D. However, in other embodiments, the frequency control function 805 (freq#{t}) is a monotonically decreasing non-linear function.

FIG. 8E shows an example frequency control function 807 (freq#{t}) in which the frequency of the signals that are generated by the bias RF signal generator 125 or primary RF signal generator 137 varies in a non-linear manner over time, in accordance with some embodiments. The frequency control function 807 (freq#{t}) is representative of the first frequency control function freq1{t} and/or the second frequency control function freq2{t}. In some embodiments, the frequency control function 807 (freq#{t}) includes both a first portion in which the frequency increases with time, and a second portion in which the frequency decreases with time.

A potential problem with current RF generators is that the DC rail voltage of the RF generator cannot be changed fast enough to implement the first RF power profile p1 and implement the transition to the second RF power profile p2 on the time scale needed. In some embodiments, one way to control the DC rail voltage of the RF generator as needed to provide the RF pulse-initiation power spike (corresponding to the first RF power profile p1) is to have two separately controllable DC power supplies within the RF generator.

In these embodiments, a first DC power supply operates to supply the necessary rail voltage to generate RF signals for the duration d402 corresponding to the second RF power profile p2 that follows the RF pulse-initiation power spike corresponding to the first RF power profile p1. Also, a second DC power supply operates to supply an additional amount of rail voltage to generate RF signals for the duration 401 of the RF pulse-initiation power spike corresponding to the first RF power profile p1. The additional amount of rail voltage supplied by the second DC power supply is added to the baseline amount of rail voltage supplied by the first DC power supply. The second DC power supply can be controlled on the time scale needed to generate the RF pulse-initiation power spike corresponding to the first RF power profile p1 and then transition at the proper time to the second RF power profile p2 of the bulk of the RF power pulse. The output of the second DC power supply is connected to a switching mechanism to control transmission of the additional amount of rail voltage to the power rail of the RF generator. In some embodiments, a capacitor or equivalent electrical device is connected to the output of the second DC power supply to enable fast switching. Also, the first and second DC power supplies are configured and connected to avoid transmission of power into each other, such as with one or more diode(s).

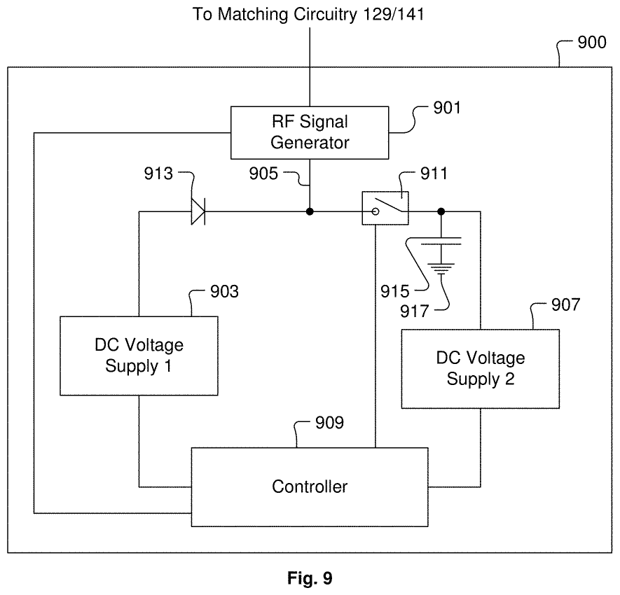

FIG. 9 shows an example arrangement of an RF signal generation system 900 that implements dual DC power supplies for RF pulse-initiation power spike generation, in accordance with some embodiments. The RF signal generation system 900 of FIG. 9 can be used for the bias RF signal generator 125 and/or the primary RF signal generator 137. The RF signal generation system 900 includes an RF signal generator 901 configured to generate RF signals at or near a set frequency. The RF signal generation system 900 also includes a first DC voltage supply 903 connected to a voltage input 905 of the RF signal generator 901. In some embodiments, the first DC voltage supply 903 is connected to the voltage input 905 through a diode 913. The diode 913 functions to protect the first DC voltage supply 903 from electrical power present at the voltage input 905 of the RF signal generator 901. The RF signal generation system 900 also includes a second DC voltage supply 907 switchably connected to the voltage input 905 of the RF signal generator 901. In some embodiments, a switching device 911 is connected between the second DC voltage supply 907 and the voltage input 905 of the RF signal generator 901. In some embodiments, a capacitor 915 or equivalent electrical device is connected between the output of the second DC voltage supply 907 and a reference ground potential 917. The capacitor 915 or equivalent electrical device ensures that the output of the second DC voltage supply 907 is electrically charged to enable fast switching of the switching device 911.

The RF signal generation system 900 also includes a controller 909 configured and connected to control each of the RF signal generator 901, the first DC voltage supply 903, the second DC voltage supply 907, and the switching device 911. In some embodiments, the controller 909 is configured similar to the control system 153. The switching device 911 is configured to control electrical connection of the second DC voltage supply 907 to the voltage input 905 of the RF signal generator 901 in accordance with control signals received from the controller 909. The voltage supplied to the voltage input 905 of the RF signal generator 901 by the first DC voltage supply 903 and the second DC voltage supply controls an amplitude of the RF signals generated by the RF signal generator 901. The controller 909 is configured to execute program instructions stored in a computer memory that when executed cause the controller 909 to direct the RF signal generator 901 to supply multiple, sequential pulses of RF power to an electrode (123/101) of the plasma processing system 100. Each of the pulses of RF power include the first duration d401 over which the first RF power profile p1 exists, immediately followed by the second duration d402 over which the second RF power profile p2 exists. The first RF power profile p1 has greater RF power than the second RF power profile p2. The first duration d401 is less than the second duration d402. Also, the sequential pulses of RF power are separated from each other by the third (interpulse) duration d403.

The first RF power profile p1 corresponds to connection of both the first DC voltage supply 903 and the second DC voltage supply 907 to the voltage input 905 of the RF signal generator 901. The second RF power profile p2 corresponds to connection of the first DC voltage supply 903 to the voltage input 905 of the RF signal generator 901, without connection of the second DC voltage supply 907 to the voltage input 905 of the RF signal generator 901. The controller 909 is configured to initiate a given pulse of RF power in accordance with the first RF power profile p1 by directing activation of the RF signal generator 901 and by directing the switching device 911 to connect the second DC voltage supply 907 to the voltage input 905 of the RF signal generator 901, with the first DC voltage supply 903 persistently connected to the voltage input 905 of the RF signal generator 901. The controller 909 is configured to transition from the first RF power profile p1 to the second RF power profile p2 by directing the switching device 911 to disconnect the second DC voltage supply 907 from the voltage input 905 of the RF signal generator 901. The controller 909 is configured to end the given pulse of RF power by directing deactivation of the RF signal generator 901.

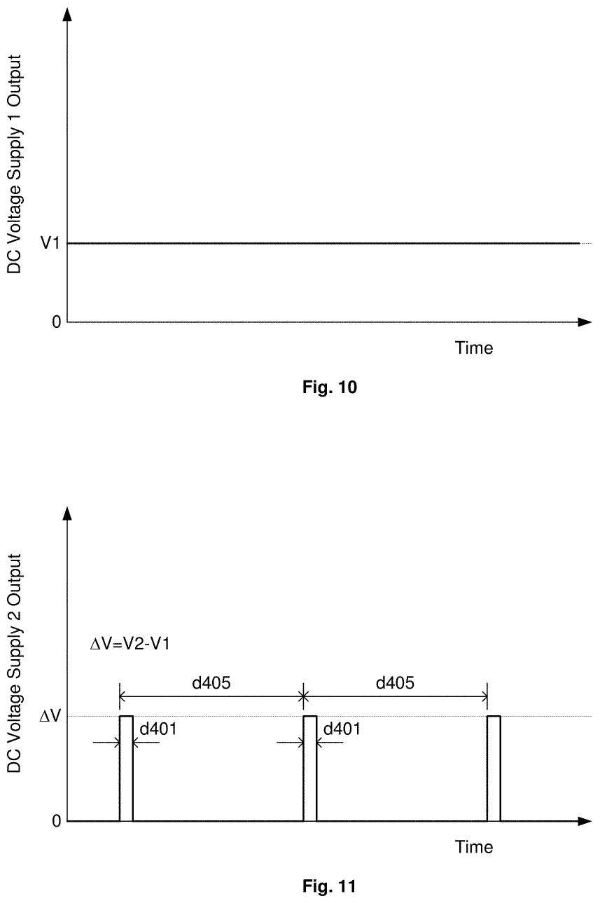

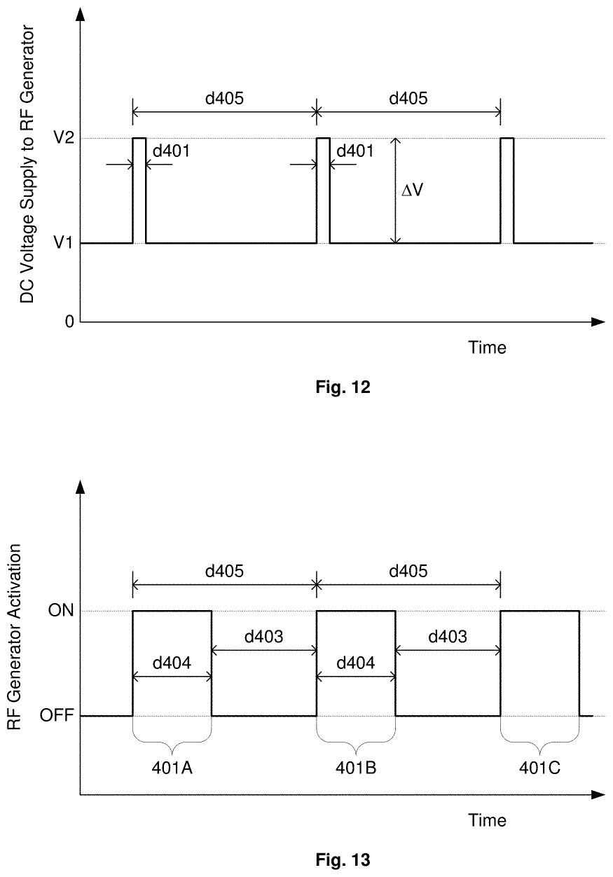

FIGS. 10, 11, and 12 collectively show voltages supplied to the voltage input 905 of the RF signal generator 901 as a function of time. FIG. 10 shows a diagram of the voltage output by the first DC voltage supply 903 as a function of time to generate the RF power pulse profile 401 of FIG. 4, in accordance with some embodiments. The voltage output by the first DC voltage supply 903 as a function of time is a substantially constant voltage V1. FIG. 11 shows a diagram of the voltage output by the second DC voltage supply 907 as a function of time to generate the RF power pulse profile 401 of FIG. 4, in accordance with some embodiments. The voltage output by the second DC voltage supply 907 as a function of time pulses between zero and a voltage ΔV, where ΔV=V2-V1, and where V2 is a voltage level corresponding to generation of the first RF power profile p1. FIG. 12 shows a diagram of the sum of the voltages output by the first DC voltage supply 903 and the second DC voltage supply 907 as a function of time to generate the RF power pulse profile 401 of FIG. 4, in accordance with some embodiments. The voltage diagram of FIG. 12 represents the voltage present at the voltage input 905 of the RF signal generator 901 as a function of time. FIG. 13 shows a diagram of the activation of the RF signal generator 901 as a function of time to generate the RF power pulse profile 401 of FIG. 4, in accordance with some embodiments. The activation of the RF signal generator 901 follows the timing of the RF power pulse profile 401 of FIG. 4 with regard to RF power pulse generation. When the RF signal generator 901 is ON, the RF signal generator 901 generates RF signals in accordance with whatever voltage is present at the voltage input 905 of the RF signal generator 901. Therefore, over the pulse duration d404, the RF signal generator 901 generates RF signals in accordance with the voltage V2 during the first duration d401 of the first RF power profile p1, and generates RF signals in accordance with the voltage V1 during the second duration d402 of the second RF power profile p2. And, when the RF signal generator 901 is OFF, no RF signals are generated by the RF signal generator 901, regardless of the voltage present at the voltage input 905 of the RF signal generator 901.

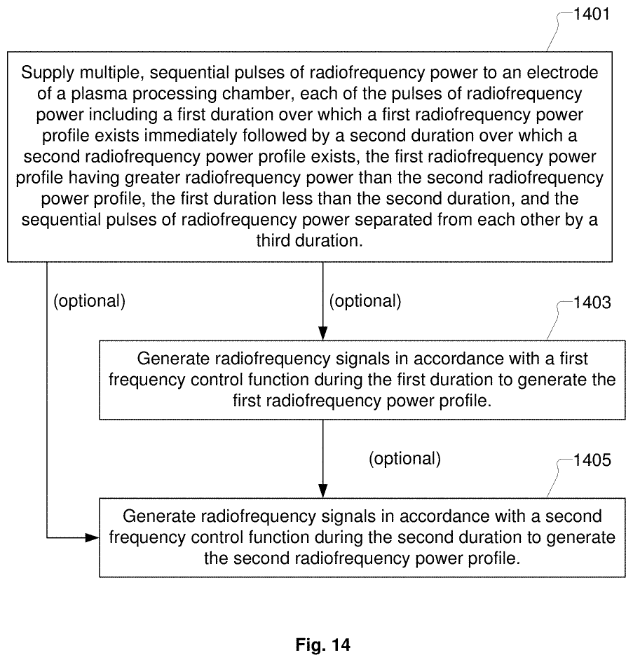

FIG. 14 shows a flowchart of a method for controlling a plasma within a plasma processing chamber, in accordance with some embodiments. In some embodiments, the plasma is generated to cause etching of a conductor material and/or a carbon-based hardmask material on a substrate. The method includes an operation 1401 for supplying multiple, sequential pulses of RF power to an electrode of the plasma processing chamber. In some embodiments, the electrode is a bias electrode disposed within a substrate holder within the plasma processing chamber. In some embodiments, the electrode is a coil disposed outside a window of the plasma processing chamber. Each of the pulses of RF power include a first duration over which a first RF power profile exists, immediately followed by a second duration over which a second RF power profile exists. The first RF power profile has greater RF power than the second RF power profile. The first duration is less than the second duration. And, the sequential pulses of RF power are separated from each other by a third duration. In some embodiments, the RF power during the third duration is essentially zero. In some embodiments, the RF power during the third duration is a substantially constant RF power level greater than zero.

In some embodiments, a sum of the first duration over which the first RF power profile exists, and the second duration over which the second RF power profile exists, and the third duration that separates sequential pulses is less than or equal to about 10 milliseconds. In some embodiments, a sum of the first duration over which the first RF power profile exists and the second duration over which the second RF power profile exists is less than or equal to the third duration that separates sequential pulses. In some embodiments, the first duration over which the first RF power profile exists is within a range extending from about 10 microseconds to about 100 microseconds, or within a range extending from about 20 microseconds to about 80 microseconds, or within a range extending from about 40 microseconds to about 50 microseconds. In some embodiments, the first duration over which the first RF power profile exists is about 5% to about 25% of a sum of the first duration and the second duration over which the second RF power profile exists. In some embodiments, the first duration over which the first RF power profile exists is about 10% to about 15% of a sum of the first duration and the second duration over which the second RF power profile exists.

In some embodiments, the first RF power profile is a substantially constant first RF power, and the second RF power profile is a substantially constant second RF power. In some embodiments, the first RF power profile decreases from a first (an initial) RF power, and the second RF power profile is a substantially constant second RF power. In some embodiments, the first RF power profile increases toward a first RF power, and the second RF power profile is a substantially constant second RF power.

In some embodiments, the method includes an optional operation 1403 for generating RF signals in accordance with a first frequency control function during the first duration to generate the first RF power profile. Also, in some embodiments, the method includes an optional operation 1405 for generating RF signals in accordance with a second frequency control function during the second duration to generate the second RF power profile. It should be understood that either or both of the optional operations 1403 and 1405 can be performed in any given embodiment. In some embodiments, a frequency tuning resolution of each of the first frequency control function and the second frequency control function is less than or equal to about 1 microsecond.

In some embodiments, the first frequency control function specifies a substantially constant frequency of the generated RF signals as a function of time. In some embodiments, the first frequency control function specifies a monotonically increasing frequency of the generated RF signals as a function of time. In some embodiments, the first frequency control function specifies a monotonically decreasing frequency of the generated RF signals as a function of time. In some embodiments, the first frequency control function specifies a non-linearly varying frequency of the generated RF signals as a function of time.

In some embodiments, the second frequency control function specifies a substantially constant frequency of the generated RF signals as a function of time. In some embodiments, the second frequency control function specifies a monotonically increasing frequency of the generated RF signals as a function of time. In some embodiments, the second frequency control function specifies a monotonically decreasing frequency of the generated RF signals as a function of time. In some embodiments, the second frequency control function specifies a non-linearly varying frequency of the generated RF signals as a function of time.

It should be understood that the systems and methods disclosed herein provide for generation of the RF pulse-initiation power spike. Also, it should be understood that the systems and methods disclosed herein provide for precise control of the amplitude and duration of the RF pulse-initiation power spike. Therefore, with the RF pulse-initiation power spike generation methods and systems disclosed herein, it is not necessary to attempt use of the open loop response of the RF signal generator in conjunction with frequency search and cable length adjustment to obtain an uncontrolled pulse initiation spike.

Also, by having a way to boost the rail voltage and/or RF drive of existing RF signal generators, and/or by creating an “ignition state” using the multi-level pulsing capabilities of existing RF signal generators, the methods and system disclosed herein provide an extra degree of control of the RF pulse-initiation power spike, which is particularly useful considering that the amplitude and duration needed in the RF pulse-initiation power spike can be different for each process recipe step. It should be understood that the methods and systems disclosed herein for generating the controlled RF pulse-initiation power spike are particularly useful when the bias RF signal generator 125 and/or primary RF signal generator 137 is/are operated in single-level pulsing mode. However, the methods and systems disclosed herein for generating the controlled RF pulse-initiation power spike are also useful when the bias RF signal generator 125 and/or primary RF signal generator 137 is/are operated in dual-level pulsing mode. And, in general, the methods and systems disclosed herein for generating the controlled RF pulse-initiation power spike are useful for the plasma striking phase of essentially any multiple phase pulse generation mode of the bias RF signal generator 125 and/or primary RF signal generator 137.

In some embodiments, the methods and systems disclosed herein for generating the controlled RF pulse-initiation power spike can be used for both supply of bias RF power to the bias electrode 123 and supply of primary RF power to the coil 101. It should be understood, however, that implementation of the methods and systems to generate the controlled RF pulse-initiation power spike for supply of bias RF power to the bias electrode 123 is/are completely independent from implementation of the methods and systems to generate the controlled RF pulse-initiation power spike for supply of primary RF power to the coil 101, and vice-versa. Generation of the controlled RF pulse-initiation power spike is particularly useful when supplying low power pulses of the primary RF power to the coil 101.

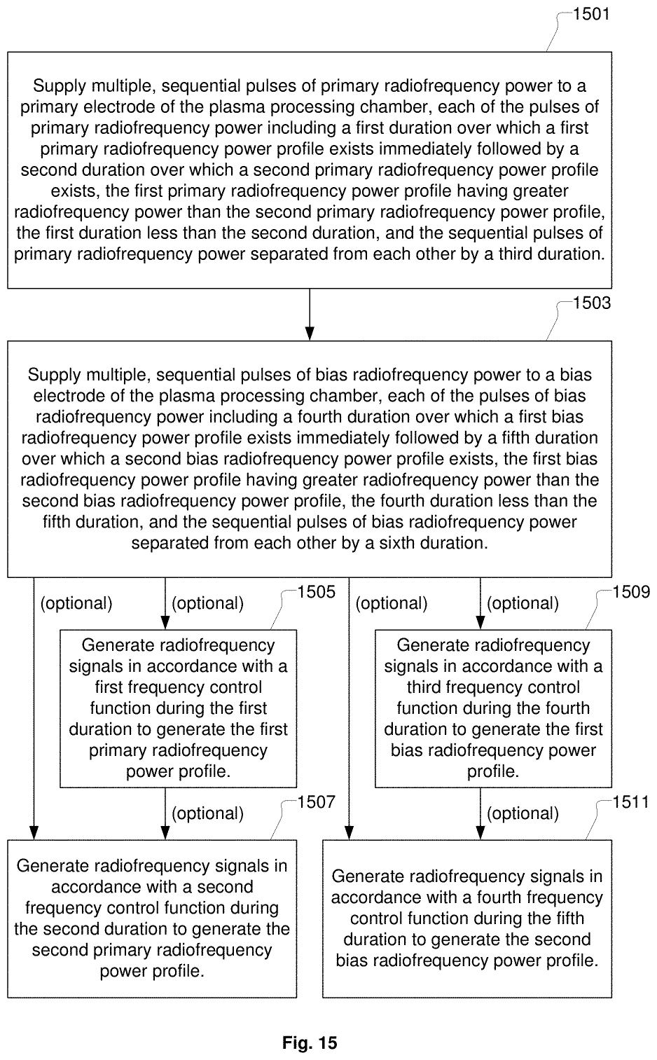

FIG. 15 shows a flowchart of a method for controlling a plasma within a plasma processing chamber, in accordance with some embodiments. The method includes an operation 1501 for supplying multiple, sequential pulses of primary RF power to a primary electrode of the plasma processing chamber. Each of the pulses of primary RF power includes a first duration over which a first primary RF power profile exists, immediately followed by a second duration over which a second primary RF power profile exists. The first primary RF power profile has greater RF power than the second primary RF power profile. The first duration is less than the second duration. And, the sequential pulses of primary RF power are separated from each other by a third duration. In some embodiments, the primary RF power level is essentially zero during the third duration. In some embodiments, the primary RF power level is a substantially constant power level greater than zero during the third duration.

The method also includes an operation 1503 for supplying multiple, sequential pulses of bias RF power to a bias electrode of the plasma processing chamber. Each of the pulses of bias RF power includes a fourth duration over which a first bias RF power profile exists, immediately followed by a fifth duration over which a second bias RF power profile exists. The first bias RF power profile has greater RF power than the second bias RF power profile. The fourth duration is less than the fifth duration. And, the sequential pulses of bias RF power are separated from each other by a sixth duration. In some embodiments, the bias RF power level is essentially zero during the sixth duration. In some embodiments, the bias RF power level is a substantially constant power level greater than zero during the sixth duration.

In some embodiments, the pulses of bias RF power are delayed relative to the pulses of primary RF power by a pulse delay amount within a range extending from about 2 microseconds to about 100 microseconds, or within a range extending from about 2 microseconds to about 5 microseconds, or of about 3 microseconds. In some embodiments, the pulse delay amount is set to enable a given pulse of primary RF power to establish a stable primary plasma condition within the plasma processing chamber before supply of a subsequent pulse of bias RF power. Also, in a dual-level primary RF power pulsing application, the impedance variation and transition of the bulk plasma between the different primary RF power levels can be significant and can require a longer delay between the primarily RF power pulse and the bias RF power pulse. This longer delay can be about 50 microseconds to about 100 microseconds.

In some embodiments, the method includes an optional operation 1505 for generating RF signals in accordance with a first frequency control function during the first duration to generate the first primary RF power profile. Also, in some embodiments, the method includes an optional operation 1507 for generating RF signals in accordance with a second frequency control function during the second duration to generate the primary second RF power profile. It should be understood that either or both of the optional operations 1505 and 1507 can be performed in any given embodiment. Additionally, in some embodiments, the method includes an optional operation 1509 for generating RF signals in accordance with a third frequency control function during the fourth duration to generate the first bias RF power profile. Also, in some embodiments, the method includes an optional operation 1511 for generating RF signals in accordance with a fourth frequency control function during the fifth duration to generate the second bias RF power profile. It should be understood that either or both of the optional operations 1509 and 1511 can be performed in any given embodiment. In some embodiments, a frequency tuning resolution of each of the first frequency control function, the second frequency control function, the third frequency control function, and the fourth frequency control function is less than or equal to about 1 microsecond.

Various embodiments described herein may also be practiced using various computer system configurations including hand-held hardware units, microprocessor systems, microprocessor-based or programmable consumer electronics, minicomputers, mainframe computers and the like. Embodiments described herein can also be practiced in distributed computing environments where tasks are performed by remote processing hardware units that are linked through a network. It should be understood that the embodiments described herein can employ various computer-implemented operations involving data stored in computer systems. These operations are those requiring physical manipulation of physical quantities. Any of the operations described herein that form part of the embodiments are useful machine operations. The embodiments also relate to a hardware unit or an apparatus for performing these operations. The apparatus may be specially constructed for a special purpose computer.

When defined as a special purpose computer, the computer can also perform other processing, program execution or routines that are not part of the special purpose, while still being capable of operating for the special purpose. In some embodiments, the operations may be processed by a general purpose computer selectively activated or configured by one or more computer programs stored in the computer memory, cache, or obtained over a network. When data is obtained over a network, the data may be processed by other computers on the network, e.g., a cloud of computing resources.

Various embodiments described herein can be implemented through process control instructions instantiated as computer-readable code on a non-transitory computer-readable medium. The non-transitory computer-readable medium is any data storage hardware unit that can store data, which can be thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes, and other optical and non-optical data storage hardware units. The non-transitory computer-readable medium can include computer-readable tangible medium distributed over a network-coupled computer system so that the computer-readable code is stored and executed in a distributed fashion.

Although the foregoing disclosure includes some detail for purposes of clarity of understanding, it will be apparent that certain changes and modifications can be practiced within the scope of the appended claims. For example, it should be understood that one or more features from any embodiment disclosed herein may be combined with one or more features of any other embodiment disclosed herein. Accordingly, the present embodiments are to be considered as illustrative and not restrictive, and what is claimed is not to be limited to the details given herein, but may be modified within the scope and equivalents of the described embodiments.

What is claimed is:

1. A method for controlling a plasma within a plasma processing chamber, comprising:
supplying multiple, sequential pulses of radiofrequency power to an electrode of the plasma processing chamber, each of the sequential pulses of radiofrequency power including a first duration over which a first radiofrequency power profile exists immediately followed by a second duration over which a second radiofrequency power profile exists, the first radiofrequency power profile having greater radiofrequency power than the second radiofrequency power profile, the first duration less than the second duration, and the sequential pulses of radiofrequency power separated from each other by a third duration.

2. The method as recited in claim 1, wherein the electrode is a bias electrode disposed within a substrate holder within the plasma processing chamber.

3. The method as recited in claim 1, wherein the electrode is a coil disposed outside a window of the plasma processing chamber.

4. The method as recited in claim 1, wherein the radiofrequency power during the third duration is essentially zero.

5. The method as recited in claim 1, wherein the radiofrequency power during the third duration is a substantially constant radiofrequency power level greater than zero.

6. The method as recited in claim 1, wherein a sum of the first duration, the second duration, and the third duration is less than or equal to about 10 milliseconds.

7. The method as recited in claim 1, wherein a sum of the first duration and the second duration is less than or equal to the third duration.

8. The method as recited in claim 1, wherein the first duration is within a range extending from about 10 microseconds to about 100 microseconds, or within a range extending from about 20 microseconds to about 80 microseconds, or within a range extending from about 40 microseconds to about 50 microseconds.

9. The method as recited in claim 1, wherein the first duration is about 5% to about 25% of a sum of the first duration and the second duration.

10. The method as recited in claim 1, wherein the first duration is about 10% to about 15% of a sum of the first duration and the second duration.

11. The method as recited in claim 1, wherein the plasma is generated to cause etching of a conductor material and/or a carbon-based hardmask material on a substrate.

12. The method as recited in claim 1, wherein the first radiofrequency power profile is a substantially constant first radiofrequency power, and wherein the second radiofrequency power profile is a substantially constant second radiofrequency power.

13. The method as recited in claim 1, wherein the first radiofrequency power profile decreases from a first radiofrequency power, and wherein the second radiofrequency power profile is a substantially constant second radiofrequency power.

14. The method as recited in claim 1, wherein the first radiofrequency power profile increases toward a first radiofrequency power, and wherein the second radiofrequency power profile is a substantially constant second radiofrequency power.

15. The method as recited in claim 1, further comprising:
generating radiofrequency signals in accordance with a first frequency control function during the first duration to generate the first radiofrequency power profile; and
generating radiofrequency signals in accordance with a second frequency control function during the second duration to generate the second radiofrequency power profile.

16. The method as recited in claim 15, wherein a frequency tuning resolution of each of the first frequency control function and the second frequency control function is less than or equal to about 1 microsecond.

17. The method as recited in claim 15, wherein the first frequency control function specifies a substantially constant frequency of the generated radiofrequency signals as a function of time, or
wherein the first frequency control function specifies a monotonically increasing frequency of the generated radiofrequency signals as a function of time, or
wherein the first frequency control function specifies a monotonically decreasing frequency of the generated radiofrequency signals as a function of time, or
wherein the first frequency control function specifies a non-linearly varying frequency of the generated radiofrequency signals as a function of time, and
wherein the second frequency control function specifies a substantially constant frequency of the generated radiofrequency signals as a function of time, or
wherein the second frequency control function specifies a monotonically increasing frequency of the generated radiofrequency signals as a function of time, or
wherein the second frequency control function specifies a monotonically decreasing frequency of the generated radiofrequency signals as a function of time, or
wherein the second frequency control function specifies a non-linearly varying frequency of the generated radiofrequency signals as a function of time.

18. A controller programmed to control a plasma within a plasma processing chamber, comprising:
program instructions stored in a computer memory that when executed direct supplying multiple, sequential pulses of radiofrequency power to an electrode of the plasma processing chamber, each of the sequential pulses of radiofrequency power including a first duration over which a first radiofrequency power profile exists immediately followed by a second duration over which a second radiofrequency power profile exists, the first radiofrequency power profile having greater radiofrequency power than the second radiofrequency power profile, the first duration less than the second duration, and the sequential pulses of radiofrequency power separated from each other by a third duration.

19. The controller as recited in claim 18, wherein the electrode is a bias electrode disposed within a substrate holder within the plasma processing chamber.

20. The controller as recited in claim 18, wherein the electrode is a coil disposed outside a window of the plasma processing chamber.

21. The controller as recited in claim 18, wherein the radiofrequency power during the third duration is essentially zero.

22. The controller as recited in claim 18, wherein the radiofrequency power during the third duration is a substantially constant radiofrequency power level greater than zero.

23-33. (canceled)
